(19) United States
(12) Patent Application Publication
(10) Pub. No.: US 2025/0380440 A1
(43) Pub. Date: Dec. 11, 2025

(54) INSULATED GATE SEMICONDUCTOR DEVICE

(71) Applicant: FUJI ELECTRIC CO., LTD., Kawasaki-shi (JP)

(72) Inventor: Koh YOSHIKAWA, Matsumoto-city (JP)

(73) Assignee: FUJI ELECTRIC CO., LTD., Kawasaki-shi (JP)

(21) Appl. No.: 19/312,516

(22) Filed: Aug. 28, 2025

Related U.S. Application Data
(63) Continuation of application No. PCT/JP2024/026284, filed on Jul. 23, 2024.

(30) Foreign Application Priority Data
Sep. 14, 2023 (JP) 2023-149076

(51) Int. Cl. H10D 12/00; H10D 12/01; H10D 62/10; H10D 62/60; H10D 64/66

(52) U.S. Cl. CPC H10D 12/481; H10D 62/103; H10D 62/126; H10D 62/60; H10D 64/661; H10D 12/038

(57) ABSTRACT

Provided is an insulated gate semiconductor device with a configuration contributing to a minimization of a mesa part between trenches. The insulated gate semiconductor device includes: a drift layer of a first conductivity-type; base regions of a second conductivity-type provided on the drift layer; contact regions of the second conductivity-type provided at upper parts of the base regions; main electrode regions of the first conductivity-type provided on the base regions and the contact regions; gate electrodes buried in gate trenches, dummy electrodes buried in dummy trenches, and contact parts buried in contact trenches, in which the contact trenches are located closer to the dummy trenches than a position away by an equal distance from each of the gate trenches and the dummy trenches.

### CROSS-REFERENCE TO RELATED APPLICATION

This application is a Continuation of PCT Application No. PCT/JP2024/026284, filed on Jul. 23, 2024, and claims the priority of Japanese Patent Application No. 2023-149076, filed on Sep. 14, 2023, the content of which are incorporated herein by reference.

### TECHNICAL FIELD

The present disclosure relates to insulated gate semiconductor devices.

### BACKGROUND ART

JP2019-186261A discloses, as illustrated in FIG. 17, a configuration in which a contact hole provided in an interlayer insulating film is arranged to be shifted toward a dummy trench from a middle part between a gate trench and the dummy trench. WO2020/213254A1 discloses, as illustrated in FIG. 4 and FIG. 5, a configuration including, in a mesa part, a trench for contact having a greater depth than an emitter region. JP2014-060387A discloses, as illustrated in FIG. 2, a configuration including a contact trench having a greater depth than an emitter region and provided with a base contact region at a bottom of the contact trench.

JP2001-168333A discloses a configuration, as illustrated in FIG. 16(c), in which an emitter electrode is provided on an insulating film and a contact region so as to be in contact with a p-type base layer, an n-type emitter layer, and a conductive body.

### SUMMARY OF THE INVENTION

### Technical Problem

The conventional insulated gate semiconductor devices with the gate trench structure have the configuration provided with the contact trench in the middle of the mesa part separated by the same distance from the respective trenches adjacent to each other in order to improve latch-up tolerance. Such a configuration, however, needs to lead the contact trench and the respective trenches to be separated from each other, which impedes minimization of the mesa part.

In view of the foregoing problems, the present disclosure provides an insulated gate semiconductor device having a configuration contributing to minimization of a mesa part between trenches.

### Solution to Problem

An aspect of the present disclosure inheres in an insulated gate semiconductor device including: a drift layer of a first conductivity-type; a base region of a second conductivity-type provided on the drift layer; a contact region of the second conductivity-type having a higher impurity concentration than the base region and provided at an upper part of the base region; a main electrode region of the first conductivity-type provided on the base region and the contact region; a gate electrode buried, with a first gate insulating film interposed, in a gate trench arranged in contact with the main electrode region and the base region; a dummy electrode buried, with a second gate insulating film interposed, in a dummy trench arranged separately from the gate trench; and a contact part buried in a contact trench arranged in contact with the main electrode region and the contact region, wherein the contact trench is located closer to the dummy trench than a position away by an equal distance from each of the gate trench and the dummy trench.

### BRIEF DESCRIPTION OF THE DRAWINGS

FIG. 1 is a vertical cross-sectional view illustrating an example of an insulated gate semiconductor device according to a first embodiment;

FIG. 2 is an enlarged cross-sectional view of region A in FIG. 1;

FIG. 3 is a horizontal cross-sectional view illustrating the example of the insulated gate semiconductor device according to the first embodiment;

FIG. 4 is a vertical cross-sectional view illustrating the example of the insulated gate semiconductor device according to the first embodiment;

FIG. 5 is a cross-sectional process view for explaining an example of a method of manufacturing the insulated gate semiconductor device according to the first embodiment;

FIG. 6 is a cross-sectional process view continued from FIG. 5, for explaining the example of the method of manufacturing the insulated gate semiconductor device according to the first embodiment;

FIG. 7 is a cross-sectional process view continued from FIG. 6, for explaining the example of the method of manufacturing the insulated gate semiconductor device according to the first embodiment;

FIG. 8 is a cross-sectional process view continued from FIG. 7, for explaining the example of the method of manufacturing the insulated gate semiconductor device according to the first embodiment;

FIG. 9 is a cross-sectional process view continued from FIG. 8, for explaining the example of the method of manufacturing the insulated gate semiconductor device according to the first embodiment;

FIG. 10 is a cross-sectional process view continued from FIG. 9, for explaining the example of the method of manufacturing the insulated gate semiconductor device according to the first embodiment;

FIG. 11 is a cross-sectional process view continued from FIG. 10, for explaining the example of the method of manufacturing the insulated gate semiconductor device according to the first embodiment;

FIG. 12 is a cross-sectional process view continued from FIG. 11, for explaining the example of the method of manufacturing the insulated gate semiconductor device according to the first embodiment;

FIG. 13 is a cross-sectional process view continued from FIG. 12, for explaining the example of the method of manufacturing the insulated gate semiconductor device according to the first embodiment;

FIG. 14 is a cross-sectional process view continued from FIG. 13, for explaining the example of the method of manufacturing the insulated gate semiconductor device according to the first embodiment;

FIG. 15 is a vertical cross-sectional view illustrating an insulated gate semiconductor device of a comparative example;

FIG. 16 is a horizontal cross-sectional view illustrating the insulated gate semiconductor device of the comparative example;

FIG. 17 is a graph showing a relation between an on-state voltage and a turn-off energy loss in the insulated gate semiconductor device according to the first embodiment;

FIG. 18 is a vertical cross-sectional view illustrating an example of an insulated gate semiconductor device according to a second embodiment;

FIG. 19 is a horizontal cross-sectional view illustrating the example of the insulated gate semiconductor device according to the second embodiment;

FIG. 20 is a horizontal cross-sectional view illustrating an example of an insulated gate semiconductor device according to a third embodiment;

FIG. 21 is a vertical cross-sectional view illustrating an example of an insulated gate semiconductor device according to a fourth embodiment;

FIG. 22 is a vertical cross-sectional view illustrating an example of an insulated gate semiconductor device according to a fifth embodiment;

FIG. 23 is an enlarged cross-sectional view of region A in FIG. 22;

FIG. 24 is a horizontal cross-sectional view illustrating the example of the insulated gate semiconductor device according to the fifth embodiment;

FIG. 25 is a horizontal cross-sectional view illustrating an example of an insulated gate semiconductor device according to a sixth embodiment;

FIG. 26 is a vertical cross-sectional view illustrating an example of an insulated gate semiconductor device according to a seventh embodiment;

FIG. 27 is a horizontal cross-sectional view illustrating an example of an insulated gate semiconductor device according to an eighth embodiment;

FIG. 28 is a vertical cross-sectional view illustrating an example of an insulated gate semiconductor device according to a ninth embodiment; and

FIG. 29 is a vertical cross-sectional view illustrating an example of an insulated gate semiconductor device according to a tenth embodiment.

### DETAILED DESCRIPTION

With reference to the drawings, first to tenth embodiments of the present disclosure will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions.

In the following description, a “first main electrode region” and a “second main electrode region” are a main electrode region of a semiconductor element, in which a main current flows in or out. The first main electrode region is assigned to a semiconductor region which is an emitter region or a collector region in an insulated gate bipolar transistor (IGBT). The first main electrode region is assigned to a semiconductor region which is a source region or a drain region in a field-effect transistor (FET) or a static induction transistor (SIT). The first main electrode region is assigned to a semiconductor region which is an anode region or a cathode region in a static induction (SI) thyristor or a gate turn-off (GTO) thyristor. The second main electrode region is assigned to a semiconductor region which is not assigned as the first main electrode region and will be the emitter region or the collector region in the IGBT, the source region or the drain region in the FET or the SIT, and the anode region or the cathode region in the SI thyristor or the GTO thyristor. That is, when the first main electrode region is the source region, the second main electrode region means the drain region. When the first main electrode region is the emitter region, the second main electrode region means the collector region. When the first main electrode region is the anode region, the second main electrode region means the cathode region. A “main electrode region” is described in the specification, the main electrode region comprehensively means any one of the first main electrode region and the second main electrode region.

Further, definitions of directions such as an up-and-down direction in the following description are merely definitions for convenience of understanding, and are not intended to limit the technical ideas of the present disclosure. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction. In addition, a “top surface” may be read as “front surface”, and a “bottom surface” may be read as “back surface”.

Further, in the following description, there is exemplified a case where a first conductivity-type is an n-type and a second conductivity-type is a p-type. However, the relationship of the conductivity types may be inverted to set the first conductivity-type to the p-type and the second conductivity-type to the n-type. Further, a semiconductor region denoted by the symbol “n” or “p” attached with “+” indicates that such semiconductor region has a relatively high impurity concentration or a relatively low specific resistance as compared to a semiconductor region denoted by the symbol “n” or “p” without “+”. A semiconductor region denoted by the symbol “n” or “p” attached with “−” indicates that such semiconductor region has a relatively low impurity concentration or a relatively high specific resistance as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration or the same specific resistance.

### First Embodiment

### <Configuration of Semiconductor Device>

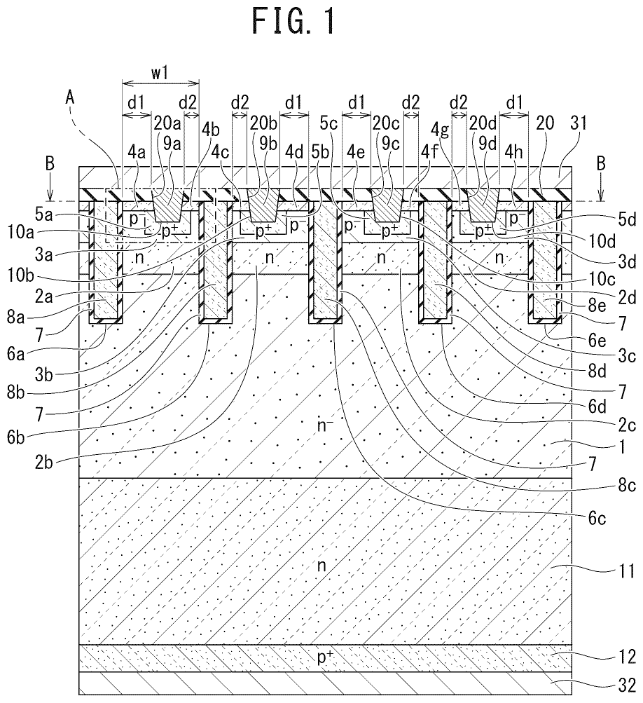

A semiconductor device according to a first embodiment is illustrated below with an IGBT. As illustrated in FIG. 1, the semiconductor device according to the first embodiment includes a drift layer 1 of a first conductivity-type (n-type). Accumulation layers 2a to 2d of n-type having a higher impurity concentration than the drift layer 1 are provided on the top surface side of the drift layer 1. The bottom surfaces of the accumulation layers 2a to 2d are in contact with the top surface of the drift layer 1. The provision of the accumulation layers 2a to 2d can increase an injection-enhancement effect (IE effect) of carriers, so as to decrease an on-state voltage. The provision of the accumulation layers 2a to 2d is optional.

Base regions 3a to 3d of a second conductivity-type (p⁻-type) are provided on the top surface side of the accumulation layers 2a to 2d. The bottom surfaces of the base regions 3a to 3d are respectively in contact with the top surfaces of the accumulation layers 2a to 2d. The bottom surfaces of the base regions 3a to 3d, if the accumulation layers 2a to 2d are not provided, are in contact with the top surface of the drift layer 1.

Contact regions 5a to 5d of the second conductivity-type (p⁺-type) having a higher impurity concentration than the base regions 3a to 3d are provided partly and selectively in the upper parts of the base regions 3a to 3d. First main electrode regions (emitter regions) 4a to 4h of n⁺-type are provided on the top surface side of the base regions 3a to 3d and the contact regions 5a to 5d. The bottom surfaces of the emitter regions 4a to 4h are in contact with the respective top surfaces of the base regions 3a to 3d and the contact regions 5a to 5d. The emitter regions 4a to 4h have a higher impurity concentration than the drift layer 1 and the accumulation layers 2a to 2d.

A plurality of trenches 6a to 6e are dug in parallel from the respective top surfaces of the emitter regions 4a to 4h separately from each other in a depth direction orthogonal to the top surfaces of the emitter regions 4a to 4h. The plural trenches 6a to 6e have the same width and depth. The plural trenches 6a to 6e penetrate the emitter regions 4a to 4h, the base regions 3a to 3d, and the accumulation layers 2a to 2d to reach the drift layer 1. The side surfaces (the side walls) of the respective trenches 6a to 6e are in contact with the respective side surfaces of the emitter regions 4a to 4h, the base regions 3a to 3d, and the accumulation layers 2a to 2d. The contact regions 5a to 5d are arranged separately from the plural trenches 6a to 6e.

A mesa part is provided between the respective trenches 6a to 6e next to each other. The mesa part is a region interposed between the respective adjacent trenches 6a to 6e, and is located above the deepest position of the respective trenches 6a to 6e. The respective mesa parts between the trenches 6a to 6e have the same width. The respective mesa parts include the upper part of the drift layer 1, the accumulation layers 2a to 2d, the base regions 3a to 3d, the contact regions 5a to 5d, and the emitter regions 4a to 4h.

The plural trenches 6a to 6e include the trenches 6a, 6c, and 6e each serving as a gate of the IGBT (referred to below as “gate trenches”), and the trenches 6b and 6d not serving as the gate of the IGBT (referred to below as “dummy trenches”). The dummy trenches 6b and 6d have a function of decreasing a capacity between a gate and a collector. While FIG. 1 illustrates the case in which the gate trenches 6a, 6c, and 6e and the dummy trenches 6b and 6d are alternately arranged, the present embodiment is not limited to this case. For example, two or more of the gate trenches may be arranged next to each other, or two or more of the dummy trenches may be arranged next to each other. The number of the gate trenches 6a, 6c, and 6e and the number of the dummy trenches 6b and 6d can be changed as appropriate.

A gate insulating film 7 is provided so as to cover the respective bottom and side surfaces of the gate trenches 6a, 6c, and 6e and the dummy trenches 6b and 6d. The gate insulating film 7 as used herein can be a single-layer film of a silicon dioxide (SiO₂) film, a silicon oxynitride (SiON) film, a strontium oxide (SrO) film, a silicon nitride (Si₃N₄) film, an aluminum oxide (Al₂O₃) film, a magnesium oxide (MgO) film, an yttrium oxide (Y₂O₃) film, a hafnium oxide (HfO₂) film, a zirconium oxide (ZrO₂) film, a tantalum oxide (Ta₂O₅) film, or a bismuth oxide (Bi₂O₃) film, or a composite film including some of the above films stacked on one another.

Gate electrodes 8a, 8c, and 8e are buried inside the gate trenches 6a, 6c, and 6e with the gate insulating film 7 interposed. The gate insulating film 7 and the gate electrodes 8a, 8c, and 8e implement insulated gate electrode structures (7, 8a), (7, 8c), and (7, 8e). The gate electrodes 8a, 8c, and 8e are electrically connected to a gate runner (not illustrated). The dummy electrodes 8b and 8d are buried inside the dummy trenches 6b and 6d with the gate insulating film 7 interposed. The dummy electrodes 8b and 8d are not connected to the gate runner (not illustrated) but are electrically connected to an emitter electrode 31 described below. The gate electrodes 8a, 8c, and 8e and the dummy electrodes 8b and 8d as used herein can each be made of a polysilicon film (a doped polysilicon film) heavily doped with n-type impurities such as phosphorus (P) or p-type impurities such as boron (B).

An interlayer insulating film 20 is provided on the respective top surfaces of the emitter regions 4a to 4h, the gate insulating film 7, the gate electrodes 8a, 8c, and 8e, and the dummy electrodes 8b and 8d. The interlayer insulating film 20 is a single-layer film of a silicon oxide film (a SiO₂ film) without containing phosphorus (P) or boron (B) which is generally referred to as a non-doped silicate glass (NSG) film, a phosphosilicate glass film (a PSG film), a borosilicate glass film (a BSG film), a borophosphosilicate glass film (a BPSG film), a silicon nitride film (a Si₃N₄ film), or a high-temperature oxide film (a HTO film), or a stacked-layer film including some of the above films stacked on one another.

The interlayer insulating film 20 is provided with contact holes 20a to 20d penetrating the interlayer insulating film 20 at positions above the respective mesa parts. The respective mesa parts are provided with trenches (contact trenches) 10a to 10d so as to be integrated with the contact holes 20a to 20d. The contact trenches 10a to 10d are dug from the top surfaces of the mesa parts in the depth direction orthogonal to the top surfaces of the mesa parts. The upper parts of the side surfaces (the side walls) of the contact trenches 10a to 10d are in contact with the emitter regions 4a to 4h. The bottom surfaces and the respective lower parts of the side surfaces (the side walls) of the contact trenches 10a to 10d are in contact with the contact regions 5a to 5d. Contact parts 9a to 9d are buried in the contact trenches 10a to 10d and the contact holes 20a to 20d. The provision of the contact trenches 10a to 10e can ensure the contact on the lower side of the emitter regions 4a to 4h, so as to decrease an influence on the emitter regions 4a to 4h by a potential made by hole current and thus improve latch-up tolerance.

A front-surface electrode (an emitter electrode) 31 is provided on the interlayer insulating film 20. The emitter electrode 31 is electrically connected to the emitter regions 4a to 4h and the contact regions 5a to 5d with the contact parts 9a to 9d interposed. The emitter electrode 31 as used herein can include metal such as aluminum (Al), an Al alloy, and copper (Cu). Examples of Al alloys include an Al-silicon (Si) alloy, an Al—Cu—Si alloy, and an Al—Cu alloy.

A field-stop (FS) layer 11 of n-type having a higher impurity concentration than the drift layer 1 is provided on the bottom surface side of the drift layer 1. The top surface of the FS layer 11 is in contact with the bottom surface of the drift layer 1. The provision of the FS layer 11 prevents a depletion layer expanding from the bottom surface side of the base regions 3a to 3d from reaching a second main electrode region (a collector region) 12 described below.

The p⁺-type collector region 12 is provided on the bottom surface side of the FS layer 11. The top surface of the collector region 12 is in contact with the bottom surface of the FS layer 11. The collector region 12 has a higher impurity concentration than the base regions 3a to 3d.

The semiconductor region defined between the respective top surfaces of the emitter regions 4a to 4h and the bottom surface of the collector region 12 is implemented by a semiconductor substrate. The semiconductor substrate is a silicon (Si) substrate, for example. The semiconductor substrate is not limited to the Si substrate, and may be a semiconductor substrate including semiconductor (wide-bandgap semiconductor) having a wider bandgap than Si, such as silicon carbide (SiC), a gallium nitride (GaN), a gallium oxide (Ga₂O₃), diamond (C), and aluminum nitride (AlN).

A rear-surface electrode (a collector electrode) 32 is provided on the bottom surface side of the collector region 12. The collector electrode 32 is made of a single film including gold (Au), or a metallic film including titanium (Ti), nickel (Ni), and gold (Au) stacked in this order, for example.

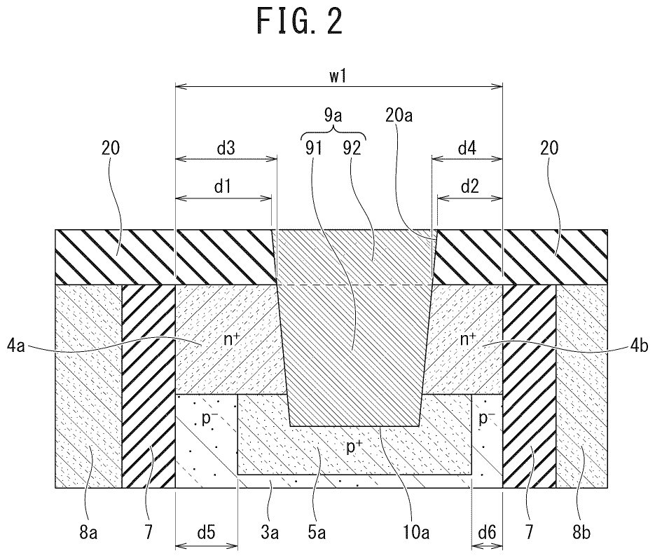

FIG. 2 is an enlarged view of region A indicated by the broken line surrounding the circumference of the contact trench 10a illustrated in FIG. 1. As illustrated in the cross-sectional view of FIG. 2, in which the emitter regions 4a and 4b appear, the contact trench 10a penetrates the emitter regions 4a and b to reach the contact region 5a. The contact trench 10a has a greater depth than the emitter regions 4a and 4b. Setting the depth of the contact trench 10a to be greater than that of the respective emitter regions 4a and 4b facilitates an increase in width of the contact region 5a in the lateral direction, so as to improve the latch-up tolerance. The depth of the trench 10a may be either the same as or shallower than that of the emitter regions 4a and 4b instead.

The side surfaces of the contact trench 10a define a taper shape (a forward taper shape) gradually narrowing from the opening toward the bottom surface. Alternatively, the side surfaces of the contact trench 10a may be substantially orthogonal to the bottom surface of the contact trench 10a, or may define a taper shape (an inverse taper shape) gradually widening from the opening toward the bottom surface. The present embodiment is illustrated with the case in which the contact trench 10a has a flat bottom surface, but is not limited to this case, and the bottom surface may be convex downward instead.

A contact part 9a is buried in the contact trench 10a and the contact hole 20a. The upper parts of the side surfaces of the contact part 9a are in contact with the emitter regions 4a and 4b and the interlayer insulating film 20. The lower parts of the side surfaces and the bottom surface of the contact part 9a are in contact with the contact region 5a. The contact of the lower parts of the side surfaces and the bottom surface of the contact part 9a with the contact region 5a can ensure the latch-up tolerance more easily than a case in which only the bottom surface of the contact part 9a is in contact with the contact region 5a. The contact part 9a is in ohmic contact with the emitter regions 4a and 4b and the contact region 5a.

The contact part 9a is implemented by a barrier metal film and a contact plug, for example. The barrier metal film as used herein can be a single-layer film including titanium (Ti), titanium nitride (TiN), or the like, or a stacked film including Ti and TiN, for example. The contact plug as used herein can include metal such as tungsten (W), for example. A metal silicide layer may be provided between the contact part 9a and each of the emitter regions 4a and 4b and the contact region 5a.

The contact part 9a may include the same material as the emitter electrode 31, or may be formed integrally with the emitter electrode 31. The contact part 9a may include material different from the emitter material instead.

The contact part 9a includes a buried part 91 and a plug part 92. The buried part 91 and the plug part 92 may be formed either integrally with each other or independently of each other. The buried part 91 is a lower part of the contact part 9a buried in the contact trench 10a. The plug part 92 is an upper part of the contact part 9a provided in the contact hole 20a.

A distance d5 toward the gate electrode 8a between the contact region 5a and the gate insulating film 7 in contact with the gate electrode 8a needs to be widely ensured in order to prevent an increase in gate threshold voltage derived from a close arrangement of the contact region 5a toward the gate electrode 8a. A distance d6 toward the dummy electrode 8b between the contact region 5a and the gate insulating film 7 in contact with the dummy electrode 8b, on the other hand, does not need to be ensured and can be zero (d6=0). The semiconductor device according to the first embodiment thus has the configuration in which the contact trench 10a and the contact part 9a are located at an asymmetric position with respect to the middle of the mesa part distant by the equal distance from each of the gate trench 6a and the dummy trench 6b so as to be located closer (shifted) to the dummy trench 6b from the middle of the mesa part.

A distance d1 in the horizontal direction from the end part of the top surface of the contact part 9a toward the gate electrode 8a (on the left side) or the end part of the opening of the contact hole 20a toward the gate electrode 8a (on the left side) to the gate insulating film 7 in contact with the side surface of the gate electrode 8a, that is, a protruding width of the interlayer insulating film 20 on the top surface side toward the gate electrode 8a, is greater than a distance d2 in the horizontal direction from the end part of the top surface of the contact part 9a toward the dummy electrode 8b (on the right side) or the end part of the opening of the contact hole 20a toward the dummy electrode 8b (on the right side) to the gate insulating film 7 in contact with the side surface of the dummy electrode 8b, that is, a protruding width of the interlayer insulating film 20 on the top surface side toward the dummy electrode 8b. For example, the distance d1 may be about 1.5 times or greater and 10 times or smaller than the distance d2.

When the contact trench 10a has the forward taper shape, the end part of the top surface of the contact part 9a on the gate electrode 8a side is located closer to the gate electrode 8a than the side surface of the contact part 9a on the gate electrode 8a side located at the same level as the bottom surface of the interlayer insulating film 20 in the horizontal direction. The distance d1 in the horizontal direction from the end part of the top surface of the contact part 9a toward the gate electrode 8a to the gate insulating film 7 in contact with the side surface of the gate electrode 8a is smaller than a distance d3 from the side surface of the contact part 9a toward the gate electrode 8a located at the same level as the bottom surface of the interlayer insulating film 20 in the horizontal direction or the end part of the top surface of the emitter region 4a toward the contact part 9a (on the right side) to the gate insulating film 7 in contact with the side surface of the gate electrode 8a, that is, a protruding width of the interlayer insulating film 20 on the bottom surface side toward the gate electrode 8a.

The end part of the top surface of the contact part 9a toward the dummy electrode 8b is located closer to the dummy electrode 8b than the side surface of the contact part 9a on the dummy electrode 8b side located at the same level as the bottom surface of the interlayer insulating film 20 in the horizontal direction. The distance d2 in the horizontal direction from the end part of the top surface of the contact part 9a toward the dummy electrode 8b to the gate insulating film 7 in contact with the side surface of the dummy electrode 8b is smaller than a distance d4 from the side surface of the contact part 9a toward the dummy electrode 8b located at the same level as the bottom surface of the interlayer insulating film 20 in the horizontal direction or the end part of the top surface of the emitter region 4b toward the contact part 9a (on the left side) to the gate insulating film 7 in contact with the side surface of the dummy electrode 8b, that is, a protruding width of the interlayer insulating film 20 on the bottom surface side toward the dummy electrode 8b.

The distance d3 from the side surface of the contact part 9a on the gate electrode 8a side located at the same level as the bottom surface of the interlayer insulating film 20 in the horizontal direction or the end part of the top surface of the emitter region 4a on the contact part 9a side to the gate insulating film 7 in contact with the side surface of the gate electrode 8a is greater than the distance d4 from the side surface of the contact part 9a on the dummy electrode 8b side located at the same level as the bottom surface of the interlayer insulating film 20 in the horizontal direction or the end part of the top surface of the emitter region 4b on the contact part 9a side to the gate insulating film 7 in contact with the side surface of the dummy electrode 8b. For example, the distance d3 may be about 1.5 times or greater and 10 times or smaller than the distance d4.

The contact trench 10b and the contact part 9b located between the dummy trench 6b and the gate trench 6c illustrated in FIG. 1 are located closer to the dummy trench 6b than a position away by the equal distance from each of the dummy trench 6b and the gate trench 6c. The contact trench 10c and the contact part 9c located between the gate trench 6c and the dummy trench 6d are located closer to the dummy trench 6d than a position away by the equal distance from each of the gate trench 6c and the dummy trench 6d. The contact trench 10d and the contact part 9d located between the dummy trench 6d and the gate trench 6e are located closer to the dummy trench 6d than a position away by the equal distance from each of the dummy trench 6d and the gate trench 6e.

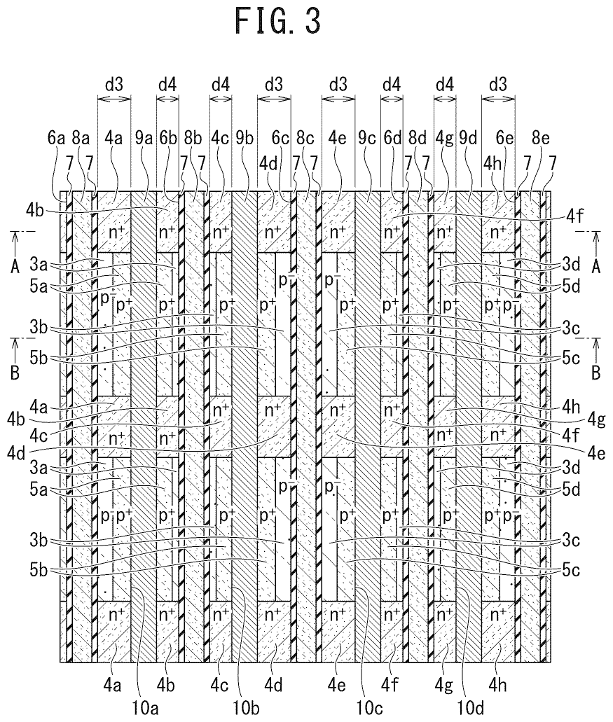

FIG. 3 is a horizontal cross-sectional view, as viewed in direction B-B on the top surface side of the semiconductor device according to the first embodiment illustrated in FIG. 1, passing through the top surfaces of the emitter regions 4a to 4h, the top surface of the gate insulating film 7, the top surfaces of the gate trenches 6a, 6c, and 6e, the top surfaces of the dummy trenches 6b and 6d, and the contact trenches 10a to 10d. The horizontal cross-sectional view as viewed in direction A-A in FIG. 3 corresponds to FIG. 1.

As illustrated in FIG. 3, the gate trenches 6a, 6c, and 6e, the dummy trenches 6b and 6d, and the contact trenches 10a to 10d each have a straight (stripe-shaped) planar pattern extending parallel to each other in one direction (the upper-lower direction in FIG. 3). The respective emitter regions 4a to 4h have a planar pattern intermittently arranged in one direction (the upper-lower direction in FIG. 3).

The emitter region 4a and the contact region 5a are in contact with the side surface on one side (on the left side) of the contact trench 10a. The emitter region 4a and the contact region 5a are arranged in contact with each other alternately and repeatedly in one direction (the upper-lower direction in FIG. 3). The emitter region 4b and the contact region 5a are in contact with the side surface on the other side (on the right side) of the contact trench 10a. The emitter region 4b and the contact region 5a are arranged in contact with each other alternately and repeatedly in one direction (the upper-lower direction in FIG. 3). The phrase “one direction (the upper-lower direction in FIG. 3)” as used herein refers to a direction in which the gate trenches 6a, 6c, and 6e, the dummy trenches 6b and 6d, and the contact trenches 10a to 10d extend parallel to each other. The one side (the left side) and the other side (the right side) each correspond to a direction orthogonal to the one direction (the upper-lower direction in FIG. 3).

The emitter region 4c and the contact region 5b are in contact with the side surface on one side (on the left side) of the contact trench 10b. The emitter region 4c and the contact region 5b are arranged in contact with each other alternately and repeatedly in one direction (the upper-lower direction in FIG. 3). The emitter region 4d and the contact region 5b are in contact with the side surface on the other side (on the right side) of the contact trench 10b. The emitter region 4d and the contact region 5b are arranged in contact with each other alternately and repeatedly in one direction (the upper-lower direction in FIG. 3).

The emitter region 4e and the contact region 5c are in contact with the side surface on one side (on the left side) of the contact trench 10c. The emitter region 4e and the contact region 5c are arranged in contact with each other alternately and repeatedly in one direction (the upper-lower direction in FIG. 3). The emitter region 4f and the contact region 5c are in contact with the side surface on the other side (on the right side) of the contact trench 10c. The emitter region 4f and the contact region 5c are arranged in contact with each other alternately and repeatedly in one direction (the upper-lower direction in FIG. 3).

The emitter region 4g and the contact region 5d are in contact with the side surface on one side (on the left side) of the contact trench 10d. The emitter region 4g and the contact region 5d are arranged in contact with each other alternately and repeatedly in one direction (the upper-lower direction in FIG. 3). The emitter region 4h and the contact region 5d are in contact with the side surface on the other side (on the right side) of the contact trench 10d. The emitter region 4h and the contact region 5d are arranged in contact with each other alternately and repeatedly in one direction (the upper-lower direction in FIG. 3).

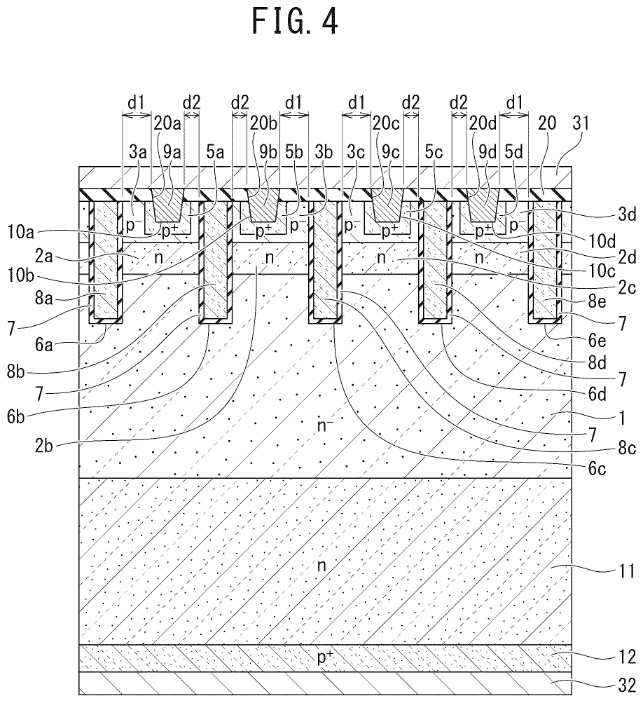

FIG. 4 is a vertical cross-sectional view as viewed in direction B-B in FIG. 3 at a position through which the emitter regions 4a to 4h do not pass. As illustrated in the cross-sectional view of FIG. 4, in which the emitter regions 4a to 3h do not appear, the respective top surfaces of the contact regions 5a to 5d are in contact with the interlayer insulating film 20. The contact of the entire side surfaces and the bottom surfaces of the contact parts 9a to 9d with the contact regions 5a to 5d can ensure the latch-up tolerance more easily than a case in which only the bottom surfaces of the contact parts 9a to 9d or only the bottom surfaces and the lower parts of the side surfaces of the contact parts 9a to 9d are in contact with the contact regions 5a to 5d.

The semiconductor device according to the first embodiment during the operation is provided with inversion layers (channels) in the base regions 3a to 3d toward the side surfaces of the gate trenches 6a, 6c, and 6e so as to be in the ON-state when a positive voltage is applied to the collector electrode 32 and a positive voltage of a threshold or greater is applied to the gate electrodes 8a, 8c, and 8e while using the emitter region 31 as a ground potential. In the ON-state, a current flows from the collector electrode 32 toward the emitter electrode 31 through the collector region 12, the FS layer 11, the drift layer 1, the accumulation layers 2a to 2d, the base regions 3a to 3d, and the emitter regions 4a, 4d, 4e, and 4h. Arranging the dummy trenches 6b and 6d next to the trenches 6a, 6c, and 6e leads a part of a gate-collector capacity (a feedback capacity) to be replaced by a collector-emitter capacity, so as to decrease the feedback capacity to improve a switching speed. When the voltage applied to the respective gate electrodes 8a, 8c, and 8e is smaller than the threshold, the semiconductor device is led to be in the OFF-state since no inversion layers are formed in the respective base regions 3a to 3d, while no current flows from the collector electrode 32 toward the emitter electrode 31.

### <Method of Manufacturing Semiconductor Device>

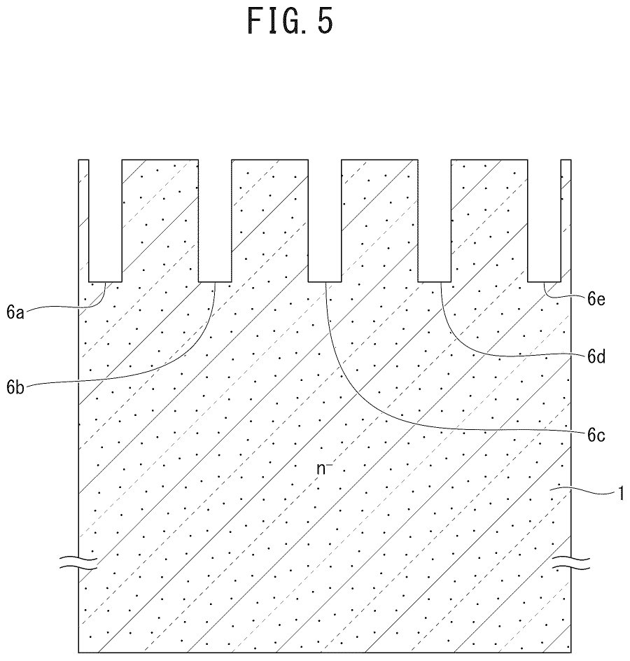

An example of a method of manufacturing the semiconductor device according to the first embodiment is described below with reference to FIG. 5 to FIG. 14 corresponding to the cross-sectional view of FIG. 1. The method of manufacturing the semiconductor device described below is one of examples, and it should be understood that the semiconductor device according to the first embodiment can be achieved by various manufacturing methods including modified examples within the scope of the appended claims.

First, a semiconductor substrate of the first conductivity-type (n-type) made of a silicon (Si) wafer, for example, is prepared. The semiconductor substrate serves as the drift layer 1. Next, the upper part of the drift layer 1 is partly and selectively removed by photolithography and dry etching. The plural trenches 6a to 6e are thus formed at the upper part of the drift layer 1, as illustrated in FIG. 5. The plural trenches 6a to be include the gate trenches 6a, 6c, and 6e and the dummy trenches 6b and 6d.

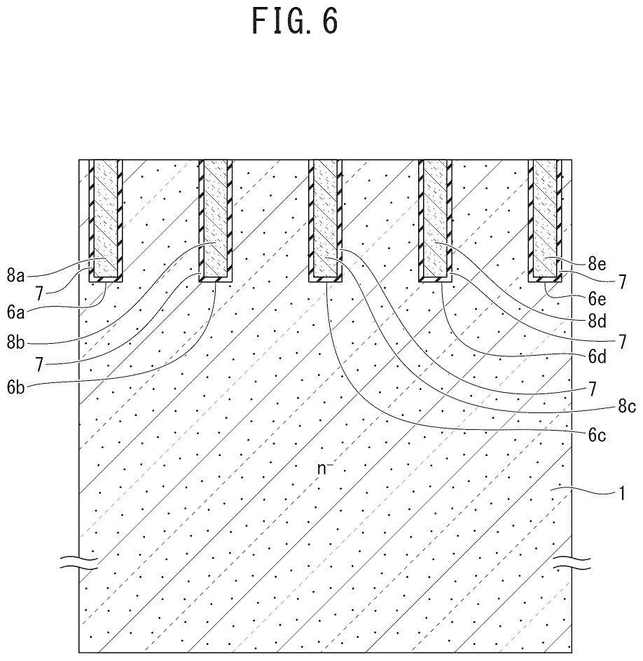

Next, the gate insulating film 7 is formed along the respective bottom and side surfaces of the gate trenches 6a, 6c, and 6e and the dummy trenches 6b and 6d by thermal oxidation or chemical vapor deposition (CVD), for example. Next, a polysilicon film (a doped polysilicon film) heavily doped with impurities such as phosphorus (P) and boron (B) is deposited by CVD or the like to fill the inside of the gate trenches 6a, 6c, and 6e and the dummy trenches 6b and 6d with the gate insulating film 7 interposed. The polysilicon film and the gate insulating film 7 on the drift layer 1 are then selectively removed by photolithography and dry etching. This step forms the insulated gate electrode structures (7, 8a), (7, 8c), and (7, 8e) implemented by the gate insulating film 7 and the gate electrodes 8a, 8c, and 8e made of the polysilicon film on the inner side of the gate trenches 6a, 6c, and 6e, as illustrated in FIG. 6. The gate insulating film 7 and the dummy electrodes 8b and 8d are also formed inside the dummy trenches 6b and 6d.

Next, p-type impurity ions such as boron (B) are implanted into the entire top surface of the drift layer 1 so as to form the p-type base regions 3a to 3d. Next, n-type impurity ions such as phosphorus (P) or arsenic (As) are implanted into the entire top surface of the drift layer 1 so as to form the n-type accumulation layers 2a to 2d. Next, a photoresist film is applied on the top surface of the drift layer 1, and is then delineated by photolithography. Using the delineated photoresist film as a mask for ion implantation, n-type impurity ions such as phosphorus (P) or arsenic (As) are implanted so as to form the n⁺-type emitter regions 4a to 4h. The photoresist film is then removed. The order of executing the ion implantation for forming the accumulation layers 2a to 2d, the ion implantation for forming the base regions 3a to 3d, and the ion implantation for forming the emitter regions 4a to 4h is not limited to the case described above and can be changed as appropriate.

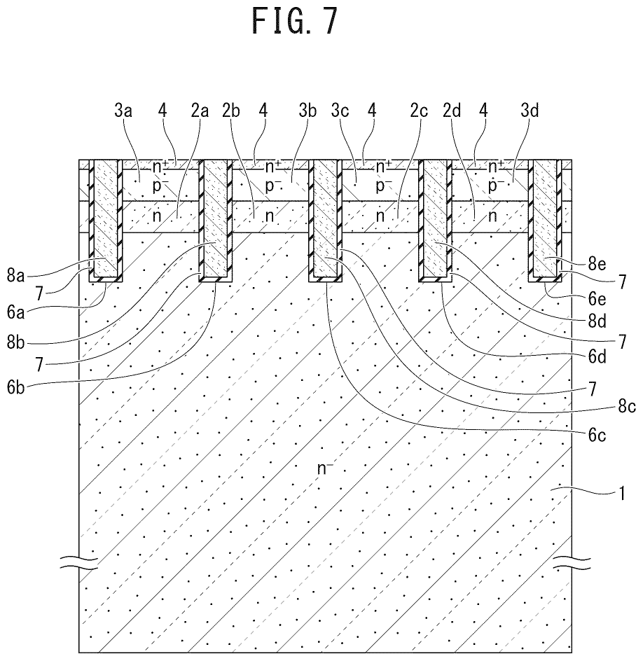

Next, the implanted impurity ions are activated by annealing. The n-type accumulation layers 2a to 2d, the p-type base regions 3a to 3d, and the n⁺-type emitter region 4 are thus formed at the upper part of the drift layer 1, as illustrated in FIG. 7. The emitter region 4 is provided intermittently in the backward direction in the sheet of FIG. 7.

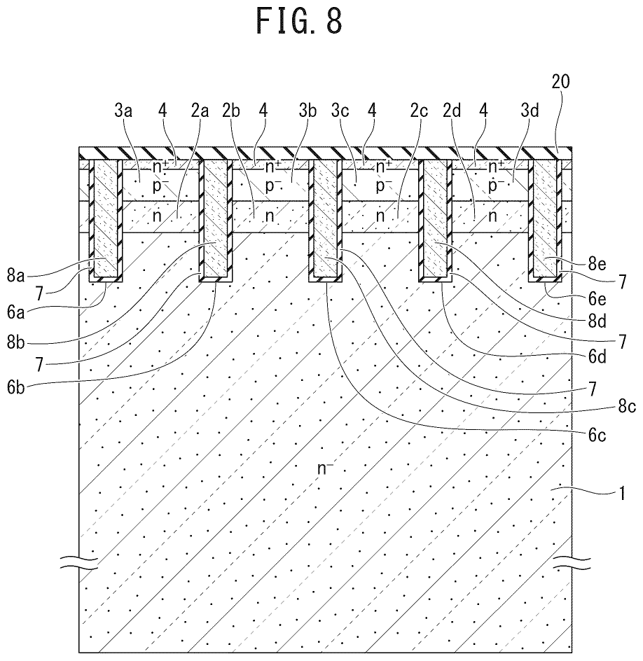

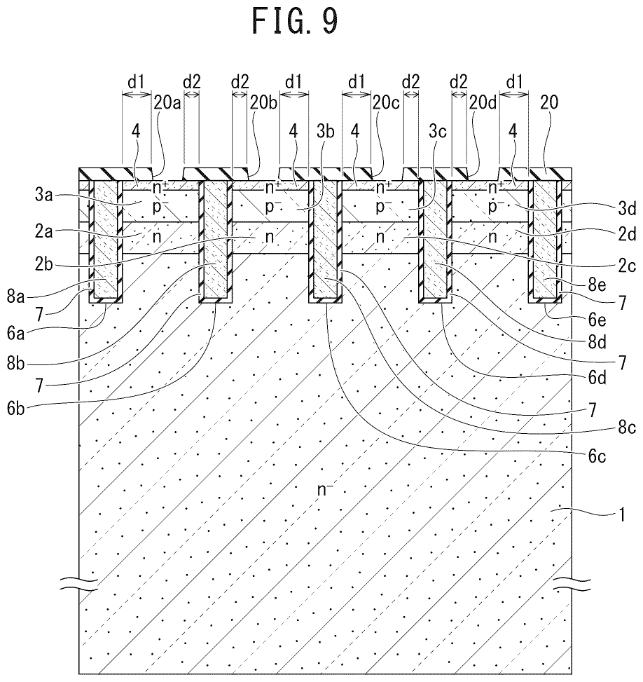

Next, the interlayer insulating film 20 is formed by CVD and the like on the respective top surfaces of the gate insulating film 7, the gate electrodes 8a, 8c, and 8e, the dummy electrodes 8b and 8d, and the emitter region 4, as illustrated in FIG. 8. A photoresist film is then applied on the top surface of the interlayer insulating film 20, and is delineated by photolithography. Using the delineated photoresist film as a mask for etching, the interlayer insulating film 20 is party and selectively removed by dry etching. The photoresist film is then removed. This step opens the contact holes 20a to 20d in the interlayer insulating film 20 so as to partly expose the top surface of the emitter region 4, as illustrated in FIG. 9.

The respective contact holes 20a to 20d in this case are open such that the distance d1 in the horizontal direction from the respective end parts of the openings of the contact holes 20a to 20d toward the respective gate electrodes 8a, 8c, and 8e to the gate insulating film 7 toward the respective gate electrodes 8a, 8c, and 8e (the protruding width on the top surface side of the interlayer insulating film 20 toward the respective gate electrodes 8a, 8c, and 8e) is set to be greater than the distance d2 in the horizontal direction from the respective end parts of the openings of the contact holes 20a to 20d toward the respective dummy electrodes 8b and 8d to the gate insulating film 7 toward the respective dummy electrodes 8b and 8d (the protruding width on the top surface side of the interlayer insulating film 20 toward the respective dummy electrodes 8b and 8d).

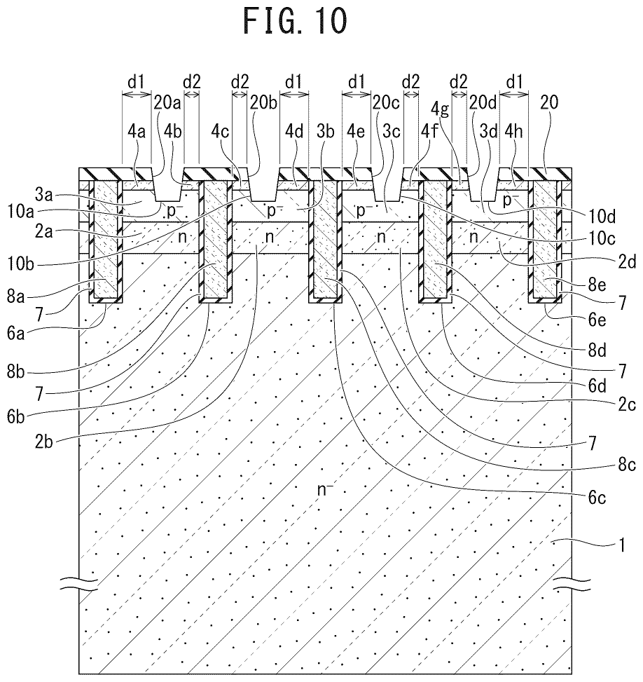

Next, the emitter region 4 and the base regions 3a to 3d in the mesa parts are partly and selectively removed by dry etching such as reactive ion etching (RIE) by use of the interlayer insulating film 20 as a mask for etching. This step forms the contact trenches 10a to 10d penetrating the emitter regions 4a to 4h to reach the base regions 3a to 3d so as to be integrated with the contact holes 20a to 20d, as illustrated in FIG. 10.

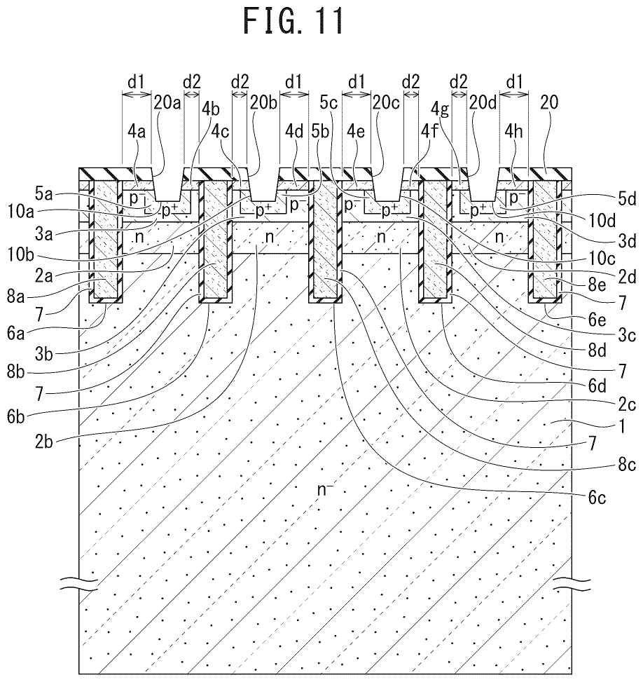

Next, p-type impurity ions such as boron (B) are implanted by use of the interlayer insulating film 20 as a mask for ion implantation. The implanted p-type impurity ions are then activated by annealing. This step forms the p⁺-type contact regions 5a to 5d at the upper parts of the base regions 3a to 3d so as to be in contact with the bottom and side surfaces of the respective contact trenches 10a to 10d, as illustrated in FIG. 11.

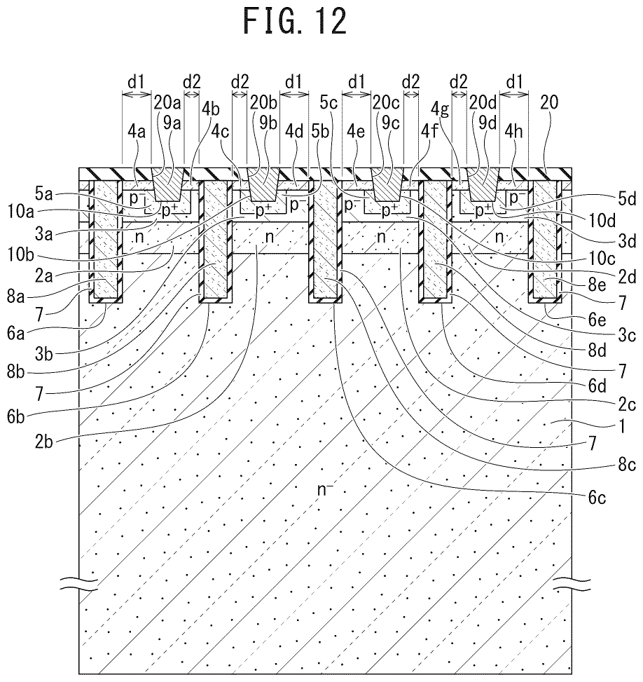

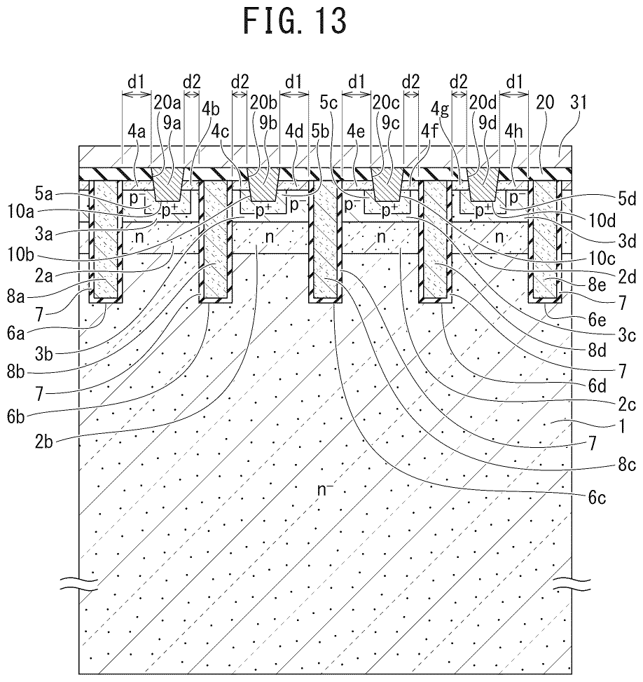

Next, a barrier metal film including titanium (Ti) and titanium nitride (TiN), for example, is formed in the contact trenches 10a to 10d and the contact holes 20a to 20d by sputtering or vapor deposition and dry etching. Next, the contact trenches 10a to 10d and the contact holes 20a to 20d are filled with contact plugs such as tungsten (W) with the barrier metal film interposed by CVD and etching back, for example. This step fills the contact trenches 10a to 10d and the contact holes 20a to 20d with the barrier metal film and the contact parts 9a to 9d made of the contact plugs, as illustrated in FIG. 12. Next, the emitter electrode 31 is deposited on the respective top surfaces of the contact parts 9a to 9d and the interlayer insulating film 20 by sputtering or vapor deposition, as illustrated in FIG. 13.

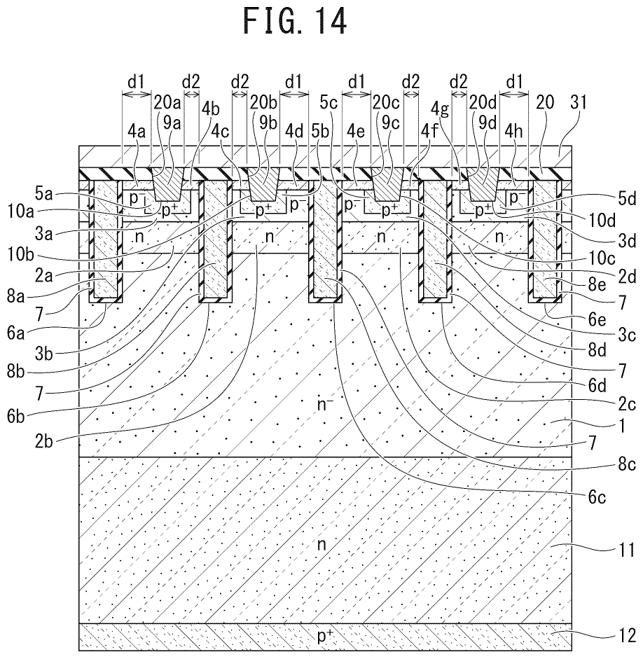

Next, the drift layer 1 is ground from the bottom surface side by grinding or chemical mechanical polishing (CMP), for example, so that the drift layer 1 is adjusted to have an intended thickness of a product. Next, n-type impurity ions such as phosphorus (P) or selenium (Se) are implanted into the entire bottom surface of the drift layer 1 so as to form the n-type FS layer 11. Next, p-type impurity ions such as boron (B) for forming the p⁺-type collector region 12 are implanted into the entire bottom surface of the drift layer 1 at a lower acceleration voltage than that upon the ion implantation executed for forming the n-type FS layer 11. Next, the implanted impurity ions are activated by annealing. This step forms the n-type FS layer 11 and the p⁺-type collector region 12 at the lower part of the drift layer 1, as illustrated in FIG. 14.

Next, the collector electrode 32 including gold (Au) is formed on the entire bottom surface of the collector region 12 by sputtering or vapor deposition, for example. Thereafter, the semiconductor substrate is cut (diced) into individual pieces, so as to complete the semiconductor device according to the first embodiment as illustrated in FIG. 1 to FIG. 4.

### COMPARATIVE EXAMPLE

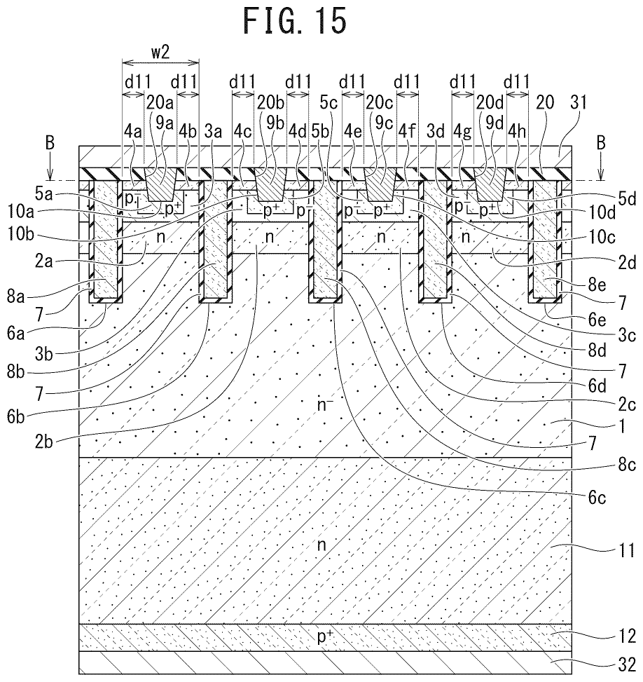

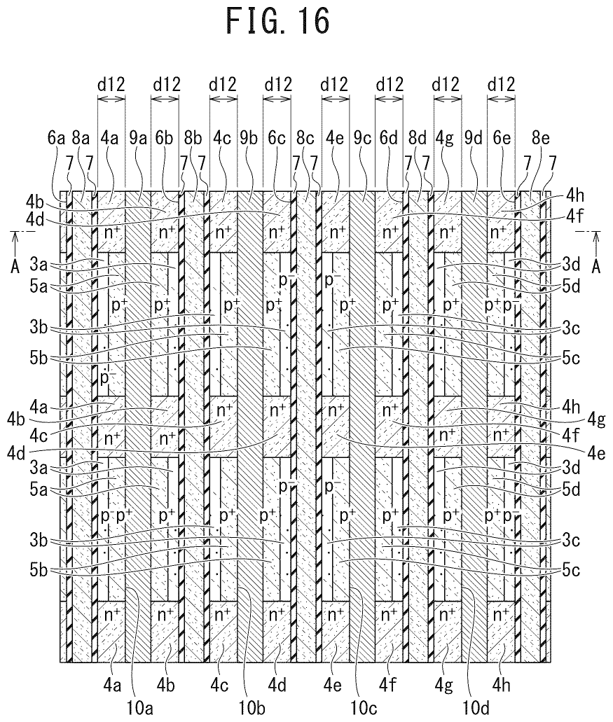

A semiconductor device of a comparative example is described below. FIG. 15 is a vertical cross-sectional view illustrating the semiconductor device of the comparative example, corresponding to the vertical cross-sectional view of the semiconductor device according to the first embodiment illustrated in FIG. 1. FIG. 16 is a horizontal cross-sectional view illustrating the semiconductor device of the comparative example, corresponding to the horizontal cross-sectional view of the semiconductor device according to the first embodiment illustrated in FIG. 2.

The semiconductor device of the comparative example differs from the semiconductor device according to the first embodiment in that the contact trenches 10a to 10d and the contact parts 9a to 9d are located in the middle of the respective mesa parts away by the equal distance from the gate trenches 6a, 6c, and 6e and the dummy trenches 6b and 6d, as illustrated in FIG. 15 and FIG. 16.

As illustrated in FIG. 15, a distance d11 in the horizontal direction from the respective end parts of the top surfaces of the contact parts 9a to 9d toward the gate electrodes 8a, 8c, and 8e to the gate insulating film 7 toward the gate electrodes 8a, 8c, and 8e is equal to a distance d11 in the horizontal direction from the respective end parts of the top surfaces of the contact parts 9a to 9d toward the dummy electrodes 8b and 8d to the gate insulating film 7 toward the dummy electrodes 8b and 8d.

As illustrated in FIG. 16, a distance d12 in the horizontal direction from the respective end parts of the top surfaces of the emitter regions 4a, 4d, 4e, and 4h toward the contact parts 9a to 9d to the gate insulating film 7 toward the gate electrodes 8a, 8c, and 8e is equal to a distance d12 in the horizontal direction from the respective end parts of the top surfaces of the emitter regions 4b, 4c, 4f, and 4g toward the contact parts 9a to 9d to the gate insulating film 7 toward the dummy electrodes 8b and 8d.

The configuration of the semiconductor device of the comparative example needs to ensure the wider distances d11 and d12 in order to arrange the contact trenches 10a to 10d and the contact parts 9a to 9d in the middle of the respective mesa parts. This configuration thus impedes a decrease of a width (a mesa width) w2 of the respective mesa parts between the gate trenches 6a, 6c, and 6e and the dummy trenches 6b and 6d.

In contrast, the semiconductor device according to the first embodiment has the configuration in which the contact trenches 10a to 10d and the contact parts 9a to 9d interposed between the gate trenches 6a, 6c, and 6e and the dummy trenches 6b and 6d are arranged to be shifted toward the dummy trenches 6b and 6d from the middle of the respective mesa parts. This configuration can decrease the distances d2 and d4 toward the dummy trenches 6b and 6d while ensuring the sufficient distances d1 and d3 toward the gate trenches 6a, 6c, and 6e, so as to decrease a width (a mesa width) w1 of the respective mesa parts. The present embodiment thus can enhance the IE effect, so as to improve the trade-off characteristics between the on-state voltage Von and the turn-off energy loss Eoff.

### Example

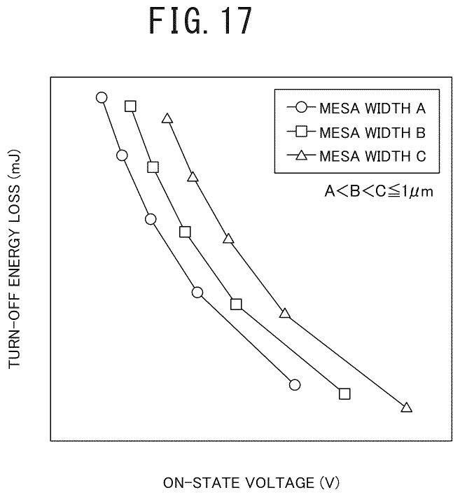

FIG. 17 is a graph showing simulation results regarding a relation between the on-state voltage Von (on-state voltage drop) and the turn-off energy loss Eoff (turn-off energy) when mesa widths A, B, and C are changed within a range of one micrometer or smaller in the semiconductor device according to the first embodiment. The results revealed, as shown in FIG. 17, that the trade-off characteristics between the on-state voltage Von and the turn-off energy loss Eoff can be further improved as the respective mesa widths A, B, and C are decreased.

### Second Embodiment

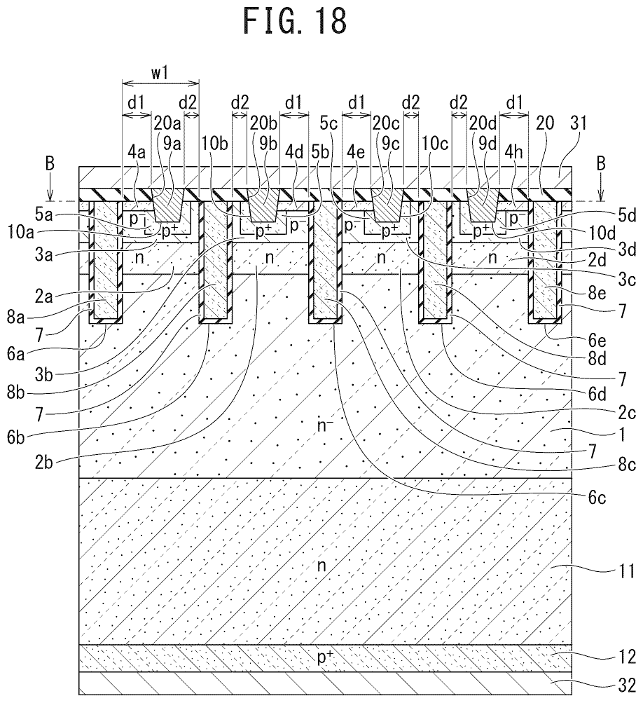

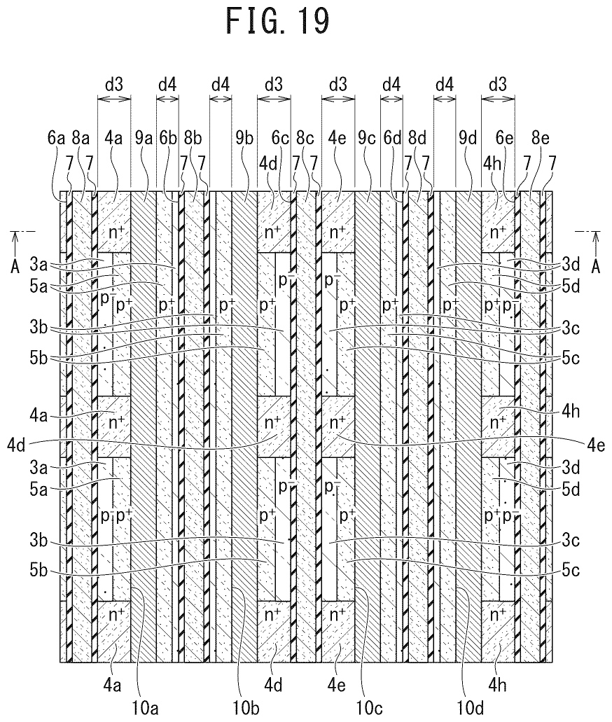

FIG. 18 is a vertical cross-sectional view illustrating an insulated gate semiconductor device according to a second embodiment, corresponding to the vertical cross-sectional view of the semiconductor device according to the first embodiment illustrated in FIG. 1. FIG. 19 is a horizontal cross-sectional view illustrating the insulated gate semiconductor device according to the second embodiment, corresponding to the horizontal cross-sectional view of the semiconductor device according to the first embodiment illustrated in FIG. 2.

The insulated gate semiconductor device according to the second embodiment differs from the insulated gate semiconductor device according to the first embodiment illustrated in FIG. 1 and FIG. 2 in not including the emitter regions toward the dummy trenches 6b and 6d but only including the emitter regions 4a, 4d, 4e, and 4h toward the gate trenches 6a, 6c, and 6e, as illustrated in FIG. 18 and FIG. 19.

As illustrated in FIG. 18, the respective top surfaces of the base regions 3a to 3d and the contact regions 5a to 5d are in contact with the interlayer insulating film 20 toward the dummy trenches 6b and 6d. As illustrated in FIG. 19, the base regions 3a to 3d and the contact regions 5a to 5d extend in a stripe state along the contact trenches 10a to 10d and the dummy trenches 6b and 6d. The other configurations of the insulated gate semiconductor device according to the second embodiment are substantially the same as those of the insulated gate semiconductor device according to the first embodiment, and overlapping explanations are not repeated.

The insulated gate semiconductor device according to the second embodiment has the configuration, as in the case of the insulated gate semiconductor device according to the first embodiment, in which the contact trenches 10a to 10d and the contact parts 9a to 9d interposed between the gate trenches 6a, 6c, and 6e and the dummy trenches 6b and 6d are arranged to be shifted toward the dummy trenches 6b and 6d from the middle of the respective mesa parts. This configuration can decrease the mesa width w1, so as to enhance the IE effect and thus improve the trade-off characteristics between the on-state voltage Von and the turn-off energy loss Eoff.

### Third Embodiment

A vertical cross-sectional view of an insulated gate semiconductor device according to a third embodiment is common to that of the semiconductor device according to the second embodiment illustrated in FIG. 18. The insulated gate semiconductor device according to the third embodiment has the same configuration as the insulated gate semiconductor device according to the second embodiment illustrated in FIG. 19 in not including the emitter regions toward the dummy trenches 6b and 6d but only including the emitter regions 4a, 4d, 4e, and 4h toward the gate trenches 6a, 6c, and 6e.

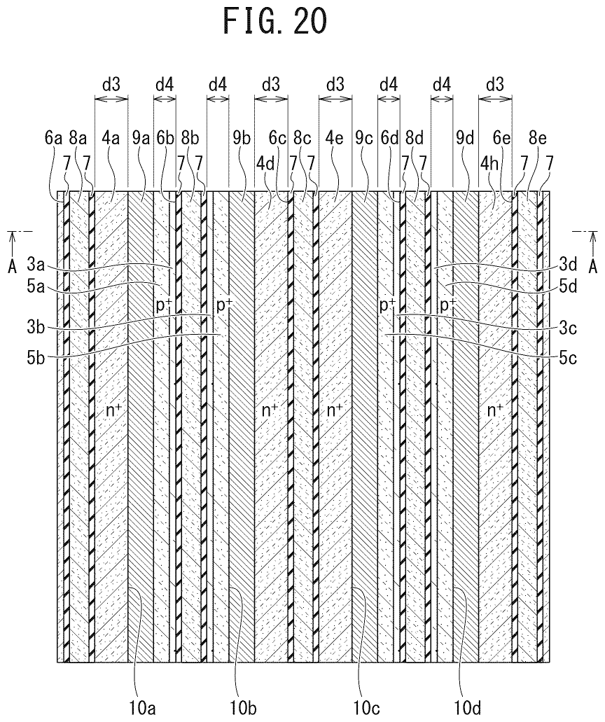

FIG. 20 is a horizontal cross-sectional view illustrating the insulated gate semiconductor device according to the third embodiment, corresponding to the horizontal cross-sectional view of the semiconductor device according to the second embodiment illustrated in FIG. 19. The insulated gate semiconductor device according to the third embodiment differs from the insulated gate semiconductor device according to the second embodiment illustrated in FIG. 19 in that the respective emitter regions 4a, 4d, 4e, and 4h have a planar pattern extending in a stripe state in one direction (the upper-lower direction in FIG. 20), as illustrated in FIG. 20. The other configurations of the insulated gate semiconductor device according to the third embodiment are substantially the same as those of the insulated gate semiconductor device according to the second embodiment, and overlapping explanations are not repeated below.

The insulated gate semiconductor device according to the third embodiment has the configuration, as in the case of the insulated gate semiconductor device according to the first embodiment, in which the contact trenches 10a to 10d and the contact parts 9a to 9d interposed between the gate trenches 6a, 6c, and 6e and the dummy trenches 6b and 6d are arranged to be shifted toward the dummy trenches 6b and 6d from the middle of the respective mesa parts. This configuration can decrease the mesa width w1, so as to enhance the IE effect and thus improve the trade-off characteristics between the on-state voltage Von and the turn-off energy loss Eoff.

### Fourth Embodiment

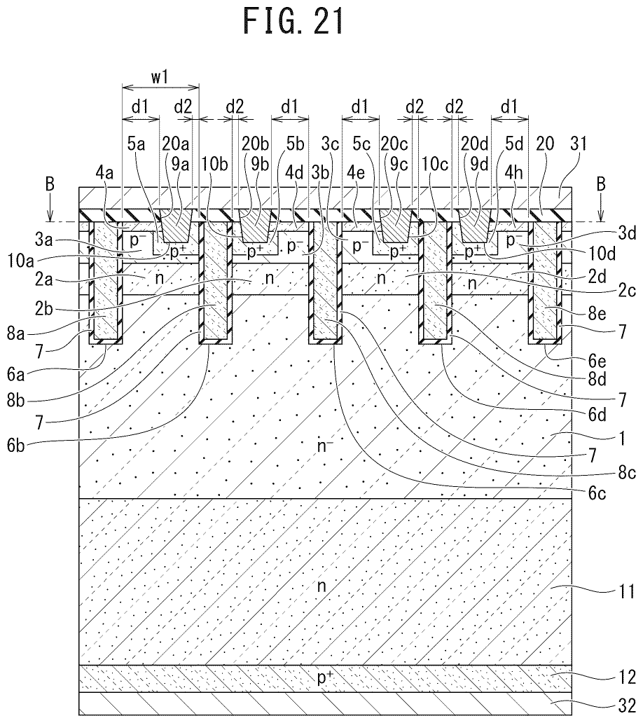

FIG. 21 is a vertical cross-sectional view illustrating an insulated gate semiconductor device according to a fourth embodiment, corresponding to the vertical cross-sectional view of the semiconductor device according to the second embodiment illustrated in FIG. 18.

The insulated gate semiconductor device according to the fourth embodiment have the same configuration as the insulated gate semiconductor device according to the second embodiment illustrated in FIG. 18 in not including the emitter regions toward the dummy trenches 6b and 6d but only including the emitter regions 4a, 4d, 4e, and 4h toward the gate trenches 6a, 6c, and 6e, as illustrated in FIG. 21. The insulated gate semiconductor device according to the fourth embodiment differs from the insulated gate semiconductor device according to the second embodiment in that the contact regions 5a to 5d are in contact with the dummy trenches 6b and 6d. The other configurations of the insulated gate semiconductor device according to the fourth embodiment are substantially the same as those of the insulated gate semiconductor device according to the second embodiment, and overlapping explanations are not repeated below.

The semiconductor device according to the fourth embodiment has the configuration, as in the case of the insulated gate semiconductor device according to the first embodiment, in which the contact trenches 10a to 10d and the contact parts 9a to 9d interposed between the gate trenches 6a, 6c, and 6e and the dummy trenches 6b and 6d are arranged to be shifted toward the dummy trenches 6b and 6d from the middle of the respective mesa parts. This configuration can decrease the mesa width w1, so as to enhance the IE effect and thus improve the trade-off characteristics between the on-state voltage Von and the turn-off energy loss Eoff.

### Fifth Embodiment

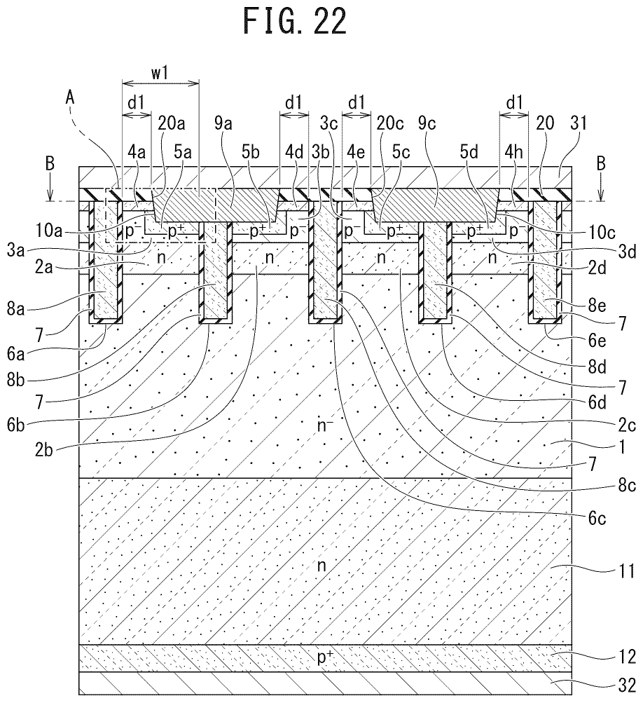

FIG. 22 is a vertical cross-sectional view illustrating an insulated gate semiconductor device according to a fifth embodiment, corresponding to the vertical cross-sectional view of the semiconductor device according to the first embodiment illustrated in FIG. 1.

The insulated gate semiconductor device according to the fifth embodiment differs from the insulated gate semiconductor device according to the first embodiment illustrated in FIG. 1 in that the contact holes 20a and 20c and the contact trenches 10a and 10c are provided over the upper side of the dummy trenches 6b and 6d, as illustrated in FIG. 22.

The upper parts of the side surfaces of the contact trench 10a are in contact with the interlayer insulating film 20 and the emitter regions 4a and 4d. The lower parts of the respective side surfaces and the bottom surface of the contact trench 10a are in contact with the contact regions 5a and 5b. The upper parts of the side surfaces of the contact trench 10c are in contact with the interlayer insulating film 20 and the emitter regions 4e and 4h. The lower parts of the respective side surfaces and the bottom surface of the contact trench 10c are in contact with the contact regions 5c and 5d.

The contact parts 9a and 9c buried in the contact holes 20a and 20c and the contact trenches 10a and 10c are in contact with the dummy electrodes 8b and 8d buried in the dummy trenches 6b and 6d.

When the dummy electrodes 8b and 8d include polysilicon doped with n-type impurities, a p-type layer may be formed also on the front surfaces of the respective dummy electrodes 8b and 8d, which could cause a p-n junction in the dummy electrodes 8b and 8d during the ion implantation for forming the contact regions 5a to 5d after the formation of the contact trenches 10a and 10c. In such a case, the potential of the respective dummy electrodes 8b and 8d is led to be a floating potential, and the breakdown voltage is thus decreased when the dummy trenches 6b and 6d on the lower surface side is led to be a high voltage. When the dummy electrodes 8b and 8d include polysilicon doped with p-type impurities, a p-n junction is not caused in the dummy electrodes 8b and 8d during the ion implantation for forming the contact regions 5a to 5d, but a conductivity is decreased because the gate electrodes 8a, 8c, and 8e formed simultaneously with the dummy electrodes 8b and 8d also include polysilicon doped with p-type impurities.

In view of this, the dummy electrodes 8b and 8d preferably include heavily-doped polysilicon including n-type impurities such as phosphorus (P) to a solid solubility limit. This configuration can prevent the p-type layer from being formed on the front surfaces of the respective dummy electrodes 8b and 8d during the ion implantation for forming the contact regions 5a to 5d, and also avoid a decrease of the conductivity. Alternatively, the dummy electrodes 8b and 8d, when including polysilicon doped with n-type impurities, may be regulated such that the impurity concentration of the respective contact regions 5a to 5d is adjusted to a level so as not to lead the p-type layer to be formed on the front surfaces of the respective dummy electrodes 8b and 8d during the ion implantation for forming the contact regions 5a to 5d.

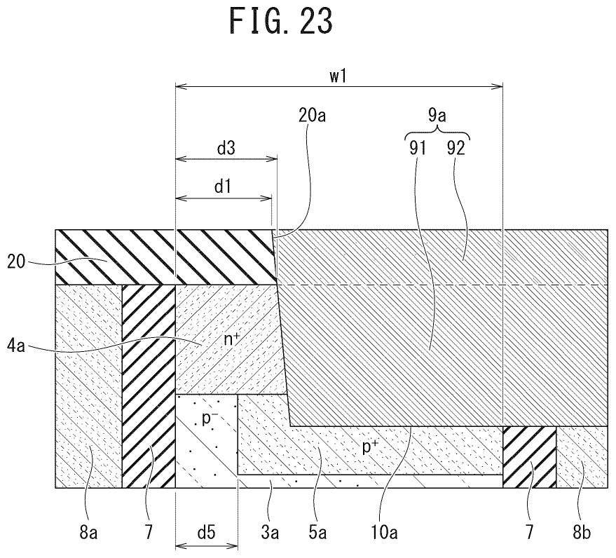

FIG. 23 is an enlarged view of region A indicated by the broken line surrounding the outer circumference of the contact trench 10a in FIG. 22. As illustrated in FIG. 23, the contact trench 10a has a greater depth than the emitter region 4a. Providing the contact trench 10a with the greater depth than the emitter region 4a facilitates an increase in width of the contact region 5a in the lateral direction, so as to improve the latch-up tolerance. The depth of the contact trench 10a can be either the same as or shallower than that of the emitter region 4a.

The side surfaces of the contact trench 10a define a taper shape (a forward taper shape) gradually narrowing from the opening toward the bottom surface. Alternatively, the side surfaces of the contact trench 10a may be substantially orthogonal to the bottom surface of the contact trench 10a, or may define a taper shape (an inverse taper shape) gradually widening from the opening toward the bottom surface. The present embodiment is illustrated with the case in which the contact trench 10a has the flat bottom surface, but is not limited to this case, and the bottom surface may be convex downward instead.

The contact part 9a is buried in the contact trench 10a and the contact hole 20a. The upper part of the side surface of the contact part 9a is in contact with the emitter region 4a and the interlayer insulating film 20. The lower part of the side surface and the bottom surface of the contact part 9a are in contact with the contact region 5a. The contact part 9a includes the buried part 91 buried in the contact trench 10a, and the plug part 92 provided in the contact hole 20a.

The distance d5 toward the gate electrode 8a between the contact region 5a and the gate insulating film 7 in contact with the gate electrode 8a needs to be widely ensured in order to prevent an increase in gate threshold voltage derived from the influence of the contact region 5a. The distance toward the dummy electrode 8b does not need to be widely ensured between the contact region 5a and the gate insulating film 7 in contact with the dummy electrode 8b. The semiconductor device according to the fifth embodiment thus has the configuration in which the contact trench 10a and the contact part 9a are arranged to be shifted toward the dummy trench 6b from a position away by the equal distance from each of the gate trench 6a and the dummy trench 6b so as to be located at the position including the upper side of the dummy trench 6b.

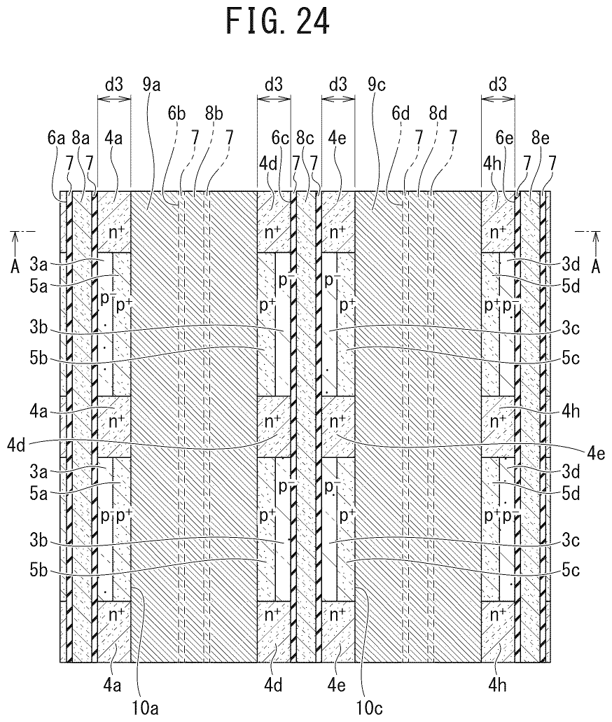

FIG. 24 is a horizontal cross-sectional view, as viewed in direction B-B on the top surface side of the semiconductor device according to the fifth embodiment illustrated in FIG. 22, passing through the top surface of the emitter regions 4a, 4d, 4e, and 4 h, the top surface of the gate insulating film 7, the top surfaces of the gate trenches 6a, 6c, and 6e, and the contact trenches 10a and 10c. The horizontal cross-sectional view as viewed in direction A-A in FIG. 24 corresponds to FIG. 22. FIG. 24 schematically indicates, by the broken lines, the dummy trenches 6b and 6d, the gate insulating film 7, and the dummy electrodes 8b and 8d hidden below the lower side of the contact trenches 10a and 10c.

As illustrated in FIG. 24, the gate trenches 6a, 6c, and 6e, the dummy trenches 6b and 6d, and the contact trenches 10a to 10d each have a straight (stripe-shaped) planar pattern extending parallel to each other in one direction (the upper-lower direction in FIG. 24). The respective emitter regions 4a to 4h have a planar pattern intermittently arranged in one direction (the upper-lower direction in FIG. 24). The other configurations of the insulated gate semiconductor device according to the fifth embodiment are substantially the same as those of the insulated gate semiconductor device according to the first embodiment, and overlapping explanations are not repeated.

The insulated gate semiconductor device according to the fifth embodiment has the configuration, as in the case of the insulated gate semiconductor device according to the first embodiment, in which the contact trenches 10a and 10c and the contact parts 9a and 9c are arranged to be shifted toward the dummy trenches 6b and 6d from the middle of the respective mesa parts. This configuration can decrease the mesa width w1, so as to enhance the IE effect and thus improve the trade-off characteristics between the on-state voltage Von and the turn-off energy loss Eoff.

Further, the configuration of the insulated gate semiconductor device according to the fifth embodiment, in which the contact holes 20a and 20c and the contact trenches 10a and 10c are provided over the upper side of the dummy trenches 6b and 6d, can further decrease the mesa width w1 than the configuration of the insulated gate semiconductor device according to the first embodiment.

### Sixth Embodiment

A vertical cross-sectional view of an insulated gate semiconductor device according to a sixth embodiment is common to that of the semiconductor device according to the fifth embodiment illustrated in FIG. 22. The insulated gate semiconductor device according to the sixth embodiment has the same configuration as the insulated gate semiconductor device according to the fifth embodiment illustrated in FIG. 22 in that the contact holes 20a and 20c and the contact trenches 10a and 10c are provided over the upper side of the dummy trenches 6b and 6d.

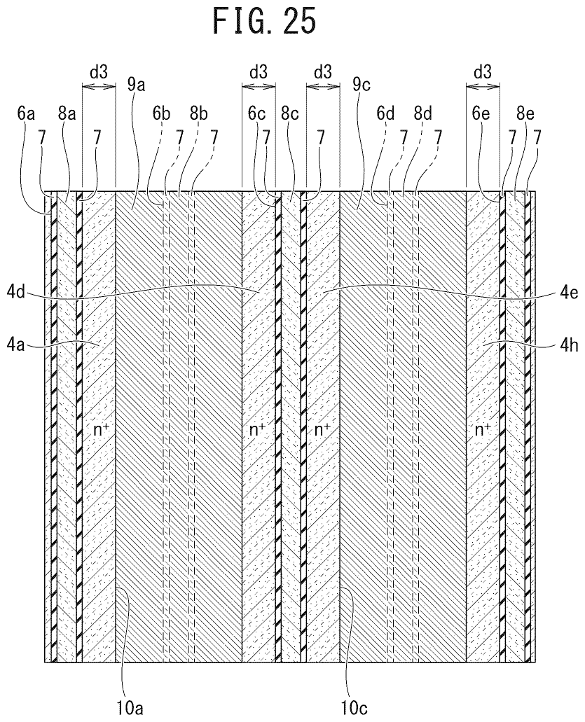

FIG. 25 is a horizontal cross-sectional view illustrating the insulated gate semiconductor device according to the sixth embodiment, corresponding to the horizontal cross-sectional view of the semiconductor device according to the fifth embodiment illustrated in FIG. 24. The insulated gate semiconductor device according to the sixth embodiment differs from the insulated gate semiconductor device according to the fifth embodiment illustrated in FIG. 24 in that the respective emitter regions 4a, 4d, 4e, and 4h have a planar pattern extending in a stripe state in one direction (the upper-lower direction in FIG. 25), as illustrated in FIG. 25. The other configurations of the insulated gate semiconductor device according to the sixth embodiment are substantially the same as those of the insulated gate semiconductor device according to the fifth embodiment, and overlapping explanations are not repeated below.

The insulated gate semiconductor device according to the sixth embodiment has the configuration, as in the case of the insulated gate semiconductor device according to the first embodiment, in which the contact trenches 10a and 10c and the contact parts 9a and 9c are arranged to be shifted toward the dummy trenches 6b and 6d from the middle of the respective mesa parts. This configuration can decrease the mesa width w1, so as to enhance the IE effect and thus improve the trade-off characteristics between the on-state voltage Von and the turn-off energy loss Eoff.

Further, the configuration of the insulated gate semiconductor device according to the sixth embodiment, in which the contact holes 20a and 20c and the contact trenches 10a and 10c are provided over the upper side of the dummy trenches 6b and 6d, can further decrease the mesa width w1 than the configuration of the insulated gate semiconductor device according to the first embodiment.

### Seventh Embodiment

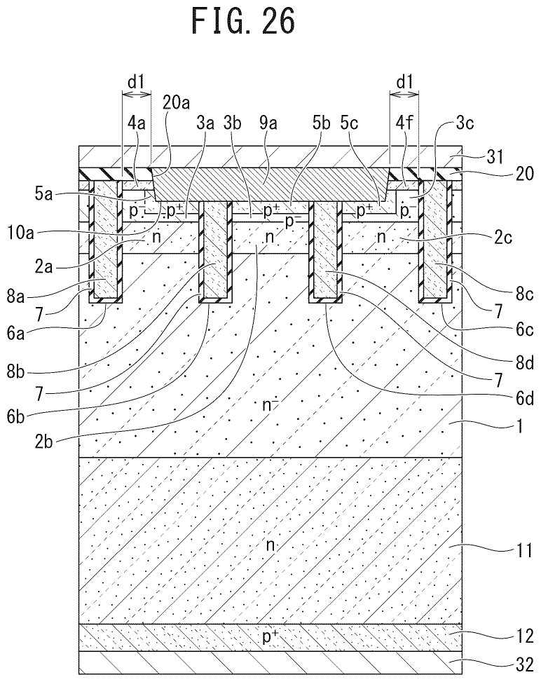

FIG. 26 is a vertical cross-sectional view illustrating an insulated gate semiconductor device according to a seventh embodiment, corresponding to the vertical cross-sectional view of the semiconductor device according to the first embodiment illustrated in FIG. 1.

The insulated gate semiconductor device according to the seventh embodiment differs from the insulated gate semiconductor device according to the first embodiment in that the dummy trenches 6b and 6d are arranged next to each other, and in that the contact hole 20a and the contact trench 10a are provided over the upper side of the respective dummy trenches 6b and 6d, as illustrated in FIG. 26. The contact part 9a buried in the contact hole 20a and the contact trench 10a is in contact with the dummy electrodes 8b and 8d buried in the dummy trenches 6b and 6d. The other configurations of the insulated gate semiconductor device according to the seventh embodiment are substantially the same as those of the insulated gate semiconductor device according to the first embodiment, and overlapping explanations are not repeated below.

The insulated gate semiconductor device according to the seventh embodiment has the configuration, as in the case of the insulated gate semiconductor device according to the first embodiment, in which the contact trench 10a and the contact part 9a are arranged to be shifted toward the dummy trenches 6b and 6d from the middle of the respective mesa parts. This configuration can decrease the mesa width, so as to enhance the IE effect and thus improve the trade-off characteristics between the on-state voltage Von and the turn-off energy loss Eoff.

Further, the configuration of the insulated gate semiconductor device according to the seventh embodiment, in which the contact hole 20a and the contact trench 10a are provided over the upper side of the dummy trenches 6b and 6d, can further decrease the mesa width than the configuration of the insulated gate semiconductor device according to the first embodiment.

### Eighth Embodiment

A vertical cross-sectional view of an insulated gate semiconductor device according to an eighth embodiment is common to that of the semiconductor device according to the first embodiment illustrated in FIG. 1.

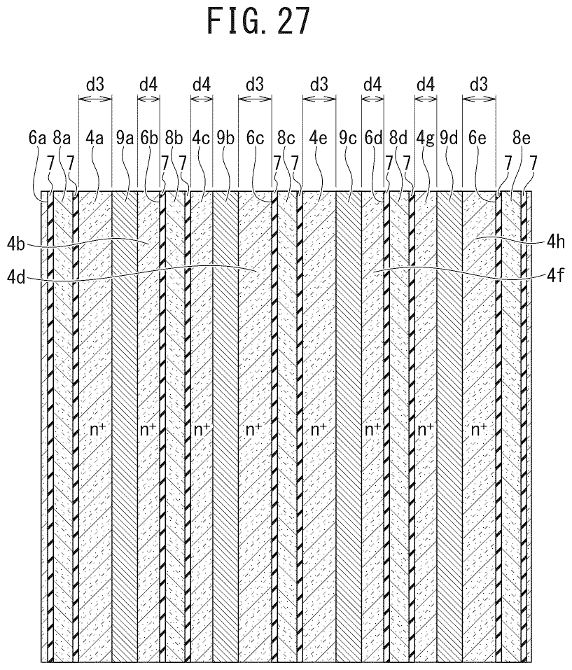

FIG. 27 is a horizontal cross-sectional view illustrating the insulated gate semiconductor device according to the eighth embodiment, corresponding to the horizontal cross-sectional view of the semiconductor device according to the first embodiment illustrated in FIG. 3. The insulated gate semiconductor device according to the eighth embodiment differs from the insulated gate semiconductor device according to the first embodiment illustrated in FIG. 3 in that the respective emitter regions 4a to 4h have a planar pattern extending in a stripe state in one direction (the upper-lower direction in FIG. 27), as illustrated in FIG. 27. The other configurations of the insulated gate semiconductor device according to the eighth embodiment are substantially the same as those of the insulated gate semiconductor device according to the first embodiment, and overlapping explanations are not repeated below.

The semiconductor device according to the eighth embodiment has the configuration, as in the case of the insulated gate semiconductor device according to the first embodiment, in which the contact trenches 10a to 10d and the contact parts 9a to 9d are arranged to be shifted toward the dummy trenches 6b and 6d from the middle of the respective mesa parts. This configuration can decrease the mesa width w1, so as to enhance the IE effect and thus improve the trade-off characteristics between the on-state voltage Von and the turn-off energy loss Eoff.

### Ninth Embodiment

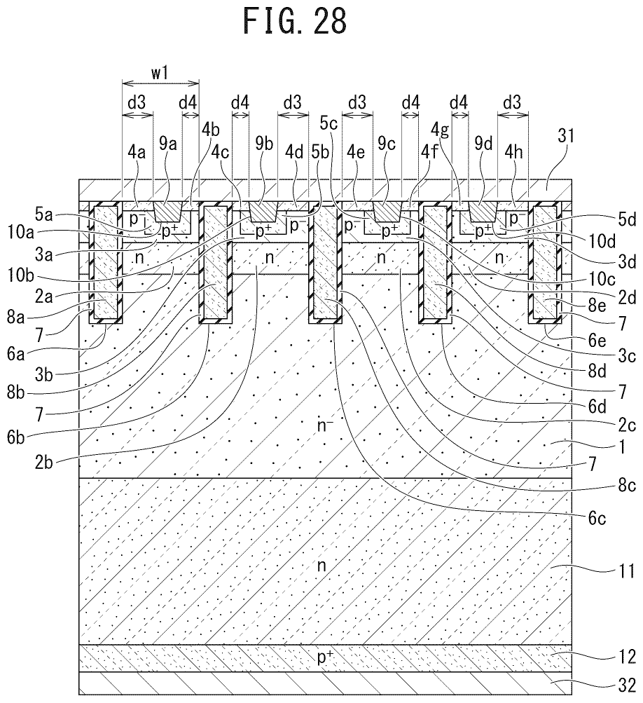

FIG. 28 is a vertical cross-sectional view illustrating an insulated gate semiconductor device according to a ninth embodiment, corresponding to the vertical cross-sectional view of the semiconductor device according to the first embodiment illustrated in FIG. 1.

The insulated gate semiconductor device according to the ninth embodiment differs from the insulated gate semiconductor device according to the first embodiment illustrated in FIG. 1 in that the interlayer insulating film 20 is not provided between the respective emitter regions 4a to 4h and the emitter electrode 31, and in that the respective top surfaces of the gate electrodes 8a, 8c, and 8e and the dummy electrodes 8b and 8d are covered with the gate insulating film 7. The other configurations of the insulated gate semiconductor device according to the ninth embodiment are substantially the same as those of the insulated gate semiconductor device according to the first embodiment, and overlapping explanations are not repeated.

The semiconductor device according to the ninth embodiment has the configuration, as in the case of the insulated gate semiconductor device according to the first embodiment, in which the contact trenches 10a to 10d and the contact parts 9a to 9d interposed between the gate trenches 6a, 6c, and 6e and the dummy trenches 6b and 6d are arranged to be shifted toward the dummy trenches 6b and 6d from the middle of the respective mesa parts. This configuration can decrease the mesa width w1, so as to enhance the IE effect and thus improve the trade-off characteristics between the on-state voltage Von and the turn-off energy loss Eoff.

### Tenth Embodiment

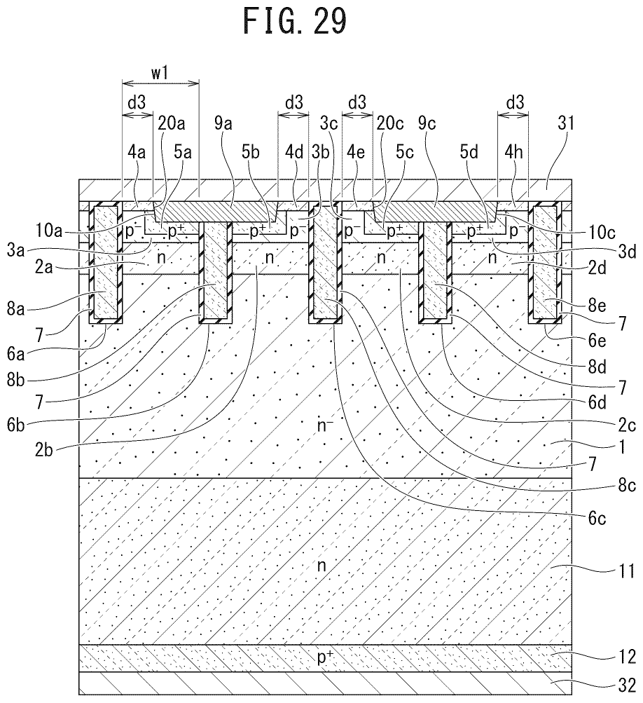

FIG. 29 is a vertical cross-sectional view illustrating an insulated gate semiconductor device according to a tenth embodiment, corresponding to the vertical cross-sectional view of the semiconductor device according to the fifth embodiment illustrated in FIG. 22.

The insulated gate semiconductor device according to the tenth embodiment differs from the insulated gate semiconductor device according to the fifth embodiment illustrated in FIG. 22 in that the interlayer insulating film 20 is not provided between the respective emitter regions 4a, 4d, 4e, and 4h and the emitter electrode 31, and in that the respective top surfaces of the gate electrodes 8a, 8c, and 8e are covered with the gate insulating film 7. The other configurations of the insulated gate semiconductor device according to the tenth embodiment are substantially the same as those of the insulated gate semiconductor device according to the fifth embodiment, and overlapping explanations are not repeated.

The insulated gate semiconductor device according to the tenth embodiment has the configuration, as in the case of the insulated gate semiconductor device according to the first embodiment, in which the contact trenches 10a and 10c and the contact parts 9a and 9c are arranged to be shifted toward the dummy trenches 6b and 6d from the middle of the respective mesa parts. This configuration can decrease the mesa width w1, so as to enhance the IE effect and thus improve the trade-off characteristics between the on-state voltage Von and the turn-off energy loss Eoff.

### Other Embodiments

As described above, the invention has been described according to the first to tenth embodiments, but it should not be understood that the description and drawings implementing a portion of this disclosure limit the invention. Various alternative embodiments of the present disclosure, examples, and operational techniques will be apparent to those skilled in the art from this disclosure.

While the respective semiconductor devices according to the first to tenth embodiments are illustrated above with the IGBT, the present invention can also be applied to a reverse conductive IGBT (RC-IGBT) or a reverse blocking IGBT (RB-IGBT). The present invention may also be applied to a MOSFET having a configuration in which an n⁺-type drain region is substituted for the p⁺-type collector region 12 included in the IGBT illustrated in FIG. 1.

In addition, the respective configurations disclosed in the first to tenth embodiments can be combined together as appropriate without contradiction with each other. As described above, the invention includes various embodiments of the present disclosure and the like not described herein. Therefore, the scope of the present disclosure is defined only by the technical features specifying the present disclosure, which are prescribed by claims, the words and terms in the claims shall be reasonably construed from the subject matters recited in the present specification.

What is claimed is:

1. An insulated gate semiconductor device comprising:
a drift layer of a first conductivity-type;
a base region of a second conductivity-type provided on the drift layer;
a contact region of the second conductivity-type having a higher impurity concentration than the base region and provided at an upper part of the base region;
a main electrode region of the first conductivity-type provided on the base region and the contact region;
a gate electrode buried, with a first gate insulating film interposed, in a gate trench arranged in contact with the main electrode region and the base region;
a dummy electrode buried, with a second gate insulating film interposed, in a dummy trench arranged separately from the gate trench; and
a contact part buried in a contact trench arranged in contact with the main electrode region and the contact region,
wherein the contact trench is located closer to the dummy trench than a position away by an equal distance from each of the gate trench and the dummy trench.

2. The insulated gate semiconductor device of claim 1, wherein the contact trench is separated from the dummy trench.

3. The insulated gate semiconductor device of claim 1, wherein a distance from a side surface of the contact part toward the gate electrode to the first gate insulating film is greater than a distance from a side surface of the contact part toward the dummy electrode to the second gate insulating film.

4. The insulated gate semiconductor device of claim 1, wherein
the contact trench is provided on an upper side of the dummy trench, and
the contact part is in contact with the dummy electrode.

5. The insulated gate semiconductor device of claim 1, wherein a depth of the contact trench is greater than a depth of the main electrode region.

6. The insulated gate semiconductor device of claim 1, wherein the contact region is separated from the dummy trench.

7. The insulated gate semiconductor device of claim 1, wherein the contact region is in contact with the dummy trench.

8. The insulated gate semiconductor device of claim 1, wherein the main electrode region is provided between the gate trench and the contact trench and between the dummy trench and the contact trench.

9. The insulated gate semiconductor device of claim 1, wherein the main electrode region is provided between the gate trench and the contact trench but is not provided between the dummy trench and the contact trench.

10. The insulated gate semiconductor device of claim 1, wherein the gate trench, the dummy trench, and the contact trench each have a planar pattern extending in one direction.

11. The insulated gate semiconductor device of claim 10, wherein the main electrode region has a planar pattern intermittently arranged in the one direction.

12. The insulated gate semiconductor device of claim 10, wherein the main electrode region has a planar pattern extending in the one direction.

13. The insulated gate semiconductor device of claim 4, wherein the dummy electrode includes polysilicon doped with impurities of the first conductivity-type to a solid solubility limit.
